(19) United States
(12) Patent Application Publication
(10) Pub. No.: US 2019/0355650 A1
(43) Pub. Date: Nov. 21, 2019

(54) SEMICONDUCTOR PACKAGE WITH CONTINUOUS LEAD FRAME

(71) Applicant: Infineon Technologies AG, Neubiberg, CA (US)

(72) Inventor: Weidong Fan, Torrance, CA (US)

(73) Assignee: Infineon Technologies Americas Corp., El Segundo, CA (US)

(21) Appl. No.: 15/984,232

(22) Filed: May 18, 2018

(51) Int. Cl. H01L 23/495; H01L 23/00

(52) U.S. Cl. CPC H01L 23/49568; H01L 23/49562; H01L 23/4952; H01L 24/48; H01L 23/3107; H01L 2224/49111; H01L 2224/48175; H01L 2224/4903; H01L 24/49

(57) ABSTRACT

A semiconductor package includes a semiconductor die, a tab, a first lead, and a continuous lead frame. The semiconductor die includes a first terminal, a second terminal, and a third terminal. The tab is electronically coupled to the first terminal. The semiconductor die is mounted on the tab. The first lead is electronically coupled to the second terminal. The continuous lead frame is electronically coupled to the third terminal and includes a second lead and a third lead.

### TECHNICAL FIELD

This disclosure relates a semiconductor package that is configured for connecting a semiconductor device to a circuit.

### BACKGROUND

Some semiconductor packages include a power transistor and pins that connect the power transistor to a circuit. The semiconductor package dissipates waste heat generated by the power transistor. A heat sink is frequently mounted to the semiconductor package to further dissipate the waste heat generated by the power transistor.

### SUMMARY

In general, this disclosure is directed to a semiconductor package design that can increase a current rating of semiconductor die, such as a power transistor. For example, a tab of a semiconductor package may be used for coupling a first terminal (e.g., a drain or a source) of the semiconductor die, a first lead may be used for coupling a second terminal (e.g., a gate) of the semiconductor die, and second and third leads may be used for coupling a third terminal (e.g., a source or a drain) of the semiconductor die. In this way, the tab and the combination of the second and third leads may dissipate heat from the semiconductor die.

In an example, a semiconductor package includes a semiconductor die comprising a first terminal, a second terminal, and a third terminal, a tab electronically coupled to the first terminal, wherein the semiconductor die is mounted on the tab, a first lead electronically coupled to the second terminal, and a continuous lead frame electronically coupled to the third terminal, the continuous lead frame comprising a second lead and a third lead.

In another example, a method includes mounting a semiconductor die to a tab, the semiconductor die comprising a first terminal, a second terminal, and a third terminal. Mounting the semiconductor die to the tab electronically couples the first terminal to the tab. The method further includes electronically coupling the second terminal to a first lead and electronically coupling the third terminal to a continuous lead frame, the continuous lead frame comprising a second lead and a third lead.

In another example, a semiconductor package includes a semiconductor die, a table, a first lead, one or more first wire bonds, and one or more second wire bonds. The semiconductor die includes a first terminal, a second terminal, and a third terminal. The tab is electronically coupled to the first terminal. The semiconductor die is mounted on the tab. The one or more first wire bonds electronically couple the second terminal to the first lead. The continuous lead frame includes a lead connection region, a second lead, and a third lead. The one or more second wire bonds electronically couple the third terminal to the lead connection region of the continuous lead frame.

Details of these and other examples are set forth in the accompanying drawings and the description below. Other features, objects, and advantages will be apparent from the description and drawings, and from the claims.

### BRIEF DESCRIPTION OF DRAWINGS

FIG. 1 is a conceptual diagram illustrating a semiconductor package for increasing a current rating of semiconductor die, in accordance with one or more techniques of this disclosure.

FIG. 2 is a conceptual diagram illustrating a first example of the semiconductor package of FIG. 1, in accordance with one or more techniques of this disclosure.

FIG. 3 is a conceptual diagram illustrating a second example of the semiconductor package of FIG. 1, in accordance with one or more techniques of this disclosure.

FIG. 4 is a conceptual diagram illustrating a third example of the semiconductor package of FIG. 1, in accordance with one or more techniques of this disclosure.

FIG. 5 is a conceptual diagram illustrating a fourth example of the semiconductor package of FIG. 1, in accordance with one or more techniques of this disclosure.

FIG. 6A-6C are conceptual illustrations of a method for providing a semiconductor package for increasing a current rating of semiconductor die, in accordance with one or more techniques of this disclosure.

FIG. 7 is a flow diagram for a method for providing a semiconductor package for increasing a current rating of semiconductor die, in accordance with one or more techniques of this disclosure.

FIG. 8 is an illustration of a performance of a semiconductor package for increasing a current rating of semiconductor die after one second, in accordance with one or more techniques of this disclosure.

FIG. 9 is an illustration of a performance of a semiconductor package for increasing a current rating of semiconductor die after five seconds, in accordance with one or more techniques of this disclosure.

FIG. 10 is an illustration of a performance of a semiconductor package for increasing a current rating of semiconductor die after sixty seconds, in accordance with one or more techniques of this disclosure.

### DETAILED DESCRIPTION

In some systems, a semiconductor package may include a tab coupled to a drain of a semiconductor die (e.g., a power transistor), a first lead coupled to a gate of the semiconductor die, a second lead coupled to a drain of the semiconductor die, and a third lead coupled to a source of the semiconductor die. However, such semiconductor packages may result in a drain-to-source (Ids) current rating that is limited by a source lead of a semiconductor package. For example, wire bonds for the source lead may have a higher temperature than the semiconductor die, which has a high thermal resistance to transfer heat through the source lead.

Rather than relying solely on reducing a thermal resistance for the source wire bonds, the semiconductor packages described herein may include a continuous lead frame that increases the drain-to-source current rating. For example, the continuous lead frame may include two leads that dissipate more heat than a single lead. Moreover, the continuous lead frame may include a lead connection region that provides a larger area for connecting wire bonds compared to semiconductor packages omitting a continuous lead frame, thereby permitting wire bonds with a lower thermal resistance than wire bonds for semiconductor packages omitting the continuous lead frame. In this way, a semiconductor die may be used at a higher power level with a lower semiconductor die temperature, which may also improve a reliability of the semiconductor die.

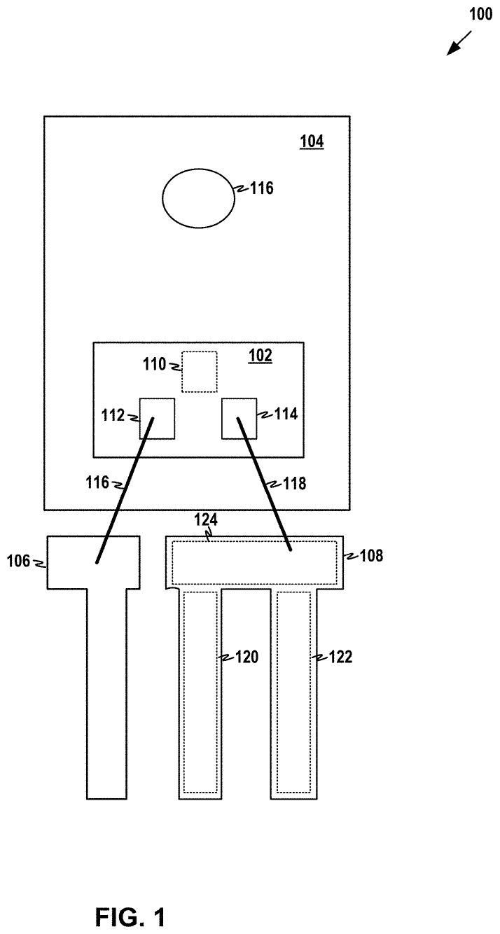

FIG. 1 is a conceptual diagram illustrating a semiconductor package 100 for increasing a current rating of semiconductor die, in accordance with one or more techniques of this disclosure. As illustrated in this example of FIG. 1, semiconductor package 100 may include semiconductor die 102, tab 104, first lead 106, and continuous lead frame 108. Examples may include additional components not illustrated in FIG. 1. For example, semiconductor package 100 may include a mold compound formed over at least a portion of tab 104, semiconductor die 102, at least a portion of first lead 106, and at least a portion of continuous lead frame 108.

Semiconductor die 102 may include a switching element. Examples of switching elements may include, but are not limited to, silicon controlled rectifier (SCR), a Field Effect Transistor (FET), and bipolar junction transistor (BJT). Examples of FETs may include, but are not limited to, junction field-effect transistor (JFET), metal-oxide-semiconductor FET (MOSFET), dual-gate MOSFET, insulated-gate bipolar transistor (IGBT), any other type of FET, or any combination of the same. Examples of MOSFETS may include, but are not limited to, PMOS, NMOS, DMOS, or any other type of MOSFET, or any combination of the same. Examples of BJTs may include, but are not limited to, PNP, NPN, heterojunction, or any other type of BJT, or any combination of the same. It should be understood that switching elements may be a high side switch or low side switch. Additionally, switching elements may be voltage-controlled and/or current-controlled. Examples of current-controlled switching elements may include, but are not limited to, gallium nitride (GaN) MOSFETs, BJTs, or other current-controlled elements.

Semiconductor die 102 includes a first terminal 110, a second terminal 112, and a third terminal 114. For example, first terminal 110 may include a drain of semiconductor die 102, second terminal 112 may include a gate of semiconductor die 102, and third terminal 114 may include a source of semiconductor die 102. In some examples, first terminal 110 may include a source of semiconductor die 102, second terminal 112 may include a gate of semiconductor die 102, and third terminal 114 may include a drain of semiconductor die 102. As indicated by the dashed lines in FIG. 1, first terminal 110 may be arranged on a back surface of semiconductor die 102. In this example, second terminal 112 and third terminal 114 may be arranged on an obverse or front surface of semiconductor die 102 that is on an opposite side of semiconductor die 102 from the back surface.

First terminal 110 may include any suitable conductive material such as, for example, but not limited to, one or more conductive elements or one or more conductive alloys. Examples of conductive element may include, but are not limited to, for example, aluminum (AL), copper (Cu), nickel (Ni), titanium (Ti), tungsten (W), another conductive element. Conductive alloys may include, for example, but not limited to, two or more of aluminum (AL), copper (Cu), nickel (Ni), titanium (Ti), tungsten (W), or another conductive element. Similarly, second terminal 112 may include any suitable conductive material such as, for example, but not limited to, one or more conductive elements or one or more conductive alloys. Further, third terminal 114 may include any suitable conductive material such as, for example, but not limited to, one or more conductive elements or one or more conductive alloys.

Tab 104 may include any suitable conductive material such as, for example, but not limited to, one or more conductive elements or one or more conductive alloys. As shown, tab 104 may include a hole 116 for mounting the semiconductor package to a heatsink. In some examples, tab 104 is electronically coupled to first terminal 110 using a conductive adhesive.

First lead 106 may include any suitable conductive material such as, for example, but not limited to, one or more conductive elements or one or more conductive alloys. First lead 106 may represent a pin suitable for attachment to a circuit, for example, an integrated circuit. For example, first lead 106 may represent a pin for attaching a gate of semiconductor die 102 to an integrated circuit.

Continuous lead frame 108 may include any suitable conductive material such as, for example, but not limited to, one or more conductive elements or one or more conductive alloys. As shown, continuous lead frame 108 may include a second lead 120, a third lead 122, and a lead connection region 124. Lead connection region 124 may represent a portion of continuous lead frame 108 suitable for attaching wire bonds.

Second lead 120 may represent a pin suitable for attachment to a circuit, for example, an integrated circuit. For example, second lead 120 may represent a pin for attaching a drain of semiconductor die 102 to an integrated circuit. In some examples, second lead 120 may represent a pin for attaching a source of semiconductor die 102 to an integrated circuit. Similarly, third lead 122 may represent a pin suitable for attachment to a circuit, for example, an integrated circuit. For example, third lead 122 may represent a pin for attaching a drain of semiconductor die 102 to an integrated circuit. In some examples, third lead 122 may represent a pin for attaching a source of semiconductor die 102 to an integrated circuit.

Wire bond 116 may represent a connection that electronically couples second terminal 112 to first lead 106. Wire bond 116 may include any suitable conductive material such as, for example, but not limited to, one or more conductive elements or one or more conductive alloys. While FIG. 1 illustrates wire bond 116 as including a single wire bond, in some examples wire bond 116 may include multiple wire bonds.

Wire bond 118 may represent a connection that electronically couples third terminal 114 to continuous lead frame 108. Wire bond 116 may include any suitable conductive material such as, for example, but not limited to, one or more conductive elements or one or more conductive alloys. While FIG. 1 illustrates wire bond 118 as including a single wire bond, in some examples, wire bond 116 may include multiple wire bonds. Although FIG. 1 illustrates wire bond 116 and wirebond 118 as having a substantially similar diameter, in some examples, wire bond 118 may have a different diameter than wire bond 116. For instance, wire bond 118 may have a larger diameter than wire bond 116.

In accordance with one or more techniques described herein, tab 104 may be electronically coupled to first terminal 110. For example, tab 104 is arranged to physically contact first terminal 110. In some instances, a conductive adhesive may be applied between tab 104 and first terminal 110. As shown in FIG. 1, semiconductor die 102 may be mounted on tab 104. In the example of FIG. 1, first lead 106 is electronically coupled to second terminal 112. For instance, wire bond 116 electronically couples second terminal 112 and first lead 106. In this example, continuous lead frame 108 is electronically coupled to third terminal 114. For instance, wire bond 118 electronically couples third terminal 114 and continuous lead frame 108. In this way, semiconductor package 100 may distribute a current (e.g., drain-to-source (Ids)) over second lead 120 and third lead 122, which reduces current density for each lead and joule heating in those leads compared to semiconductor packages that do not include continuous lead frame 108.

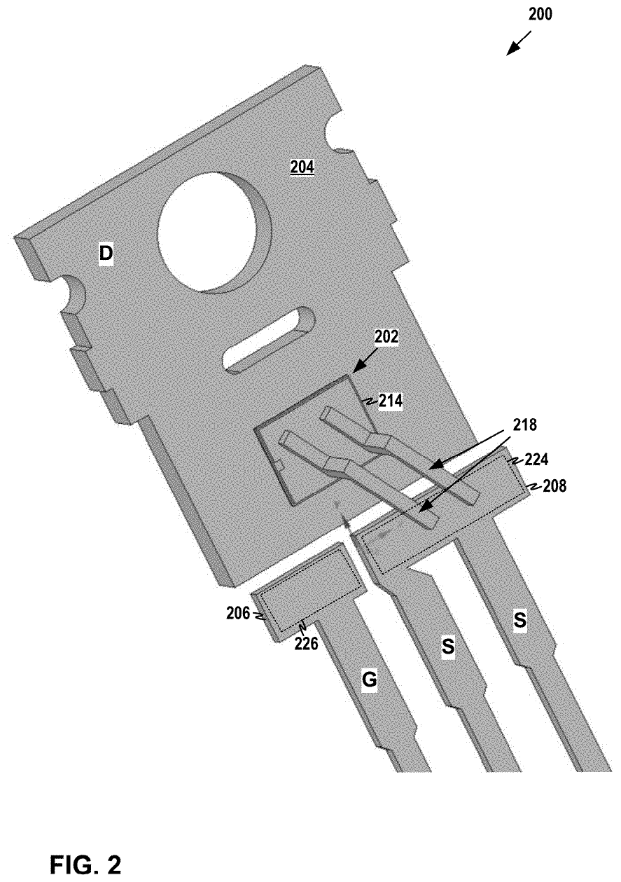

FIG. 2 is a conceptual diagram illustrating a first example of the semiconductor package 100 of FIG. 1, in accordance with one or more techniques of this disclosure. As illustrated, semiconductor package 200 includes semiconductor die 202, tab 204, first lead 206, and continuous lead frame 208. Semiconductor die 202 may be an example of semiconductor die 102 of FIG. 1. Tab 204 may be an example of tab 104 of FIG. 1. First lead 206 may be an example of first lead 106 of FIG. 1. Continuous lead frame 208 may be an example of continuous lead frame 108 of FIG. 1.

In the example of FIG. 2, first lead 206 represents a gate of semiconductor die 202. As shown, tab 204 represents a drain of semiconductor die 202. In this example, continuous lead frame 208 represents a source of semiconductor die 202. Wire bonds 218 electronically couple third terminal 214 to lead connection region 224 of continuous lead frame 208. As such, a drain-to-source (Ids) current may flow from tab 204 to continuous lead frame 208. In this way, semiconductor package 200 may distribute the drain-to-source (Ids) current over continuous lead frame 208, which may reduce current density for each lead of continuous lead frame 208 and joule heating in continuous lead frame 208 compared to semiconductor packages that do not include continuous lead frame 208.

In the example of FIG. 2, lead connection region 224 is larger than a lead connection region 226 of first lead 206, which, in some instances, may be representative of a lead connection region for a single lead. As such, lead connection region 224 may permit wire bonds 218 to include relatively large wire bonds with a relatively low thermal resistance compared to wire bonds (not shown) for connecting to lead connection region 226 of first lead 206. In this way, semiconductor die 202 may be used at a higher power level with a lower semiconductor die temperature compared to semiconductor packages that do not include continuous lead frame 208, which may also improve a reliability of semiconductor die 202 compared to semiconductor packages that do not include continuous lead frame 208.

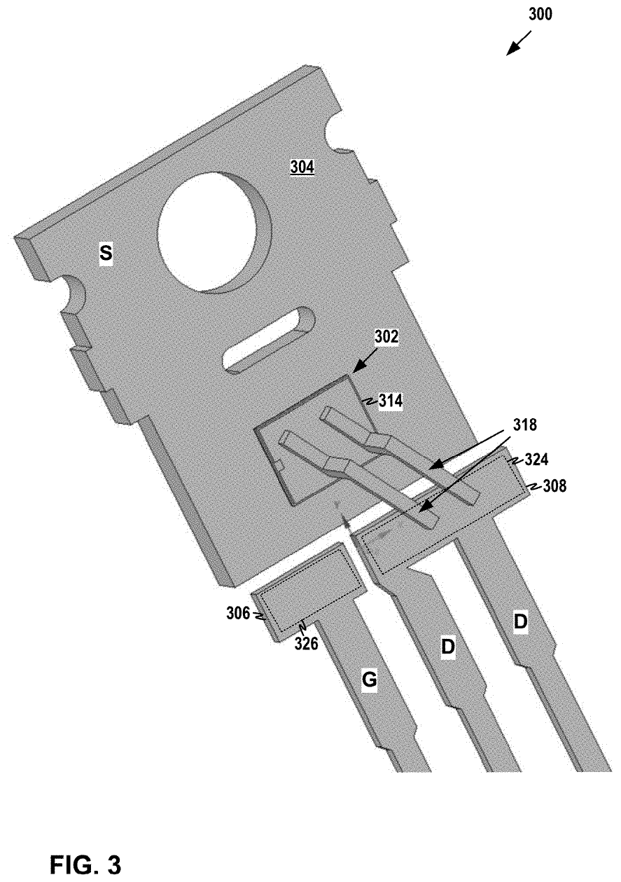

FIG. 3 is a conceptual diagram illustrating a second example of the semiconductor package 100 of FIG. 1, in accordance with one or more techniques of this disclosure. As illustrated, semiconductor package 300 includes semiconductor die 302, tab 304, first lead 306, and continuous lead frame 308. Semiconductor die 302 may be an example of semiconductor die 102 of FIG. 1. Tab 304 may be an example of tab 104 of FIG. 1. First lead 306 may be an example of first lead 106 of FIG. 1. Continuous lead frame 308 may be an example of continuous lead frame 108 of FIG. 1.

In the example of FIG. 3, first lead 306 represents a gate of semiconductor die 302. As shown, tab 304 represents a source of semiconductor die 302. In this example, continuous lead frame 308 represents a drain of semiconductor die 302. Wire bonds 318 electronically couple third terminal 314 to lead connection region 324 of continuous lead frame 308. As such, a drain-to-source (Ids) current may flow from continuous lead frame 308 to tab 304. In this way, semiconductor package 300 may distribute the drain-to-source (Ids) current over continuous lead frame 308, which may reduce current density for each lead of continuous lead frame 308 and joule heating in continuous lead frame 308 compared to semiconductor packages that do not include continuous lead frame 308.

In the example of FIG. 3, lead connection region 324 is larger than a lead connection region 326 of first lead 306, which, in some instances, may be representative of a lead connection region for a single lead. As such, lead connection region 324 may permit wire bonds 318 to include relatively large wire bonds with a relatively low thermal resistance compared to wire bonds (not shown) for connecting to lead connection region 326 of first lead 306. In this way, semiconductor die 302 may be used at a higher power level with a lower semiconductor die temperature compared to semiconductor packages that do not include continuous lead frame 308, which may also improve a reliability of semiconductor die 302 compared to semiconductor packages that do not include continuous lead frame 308.

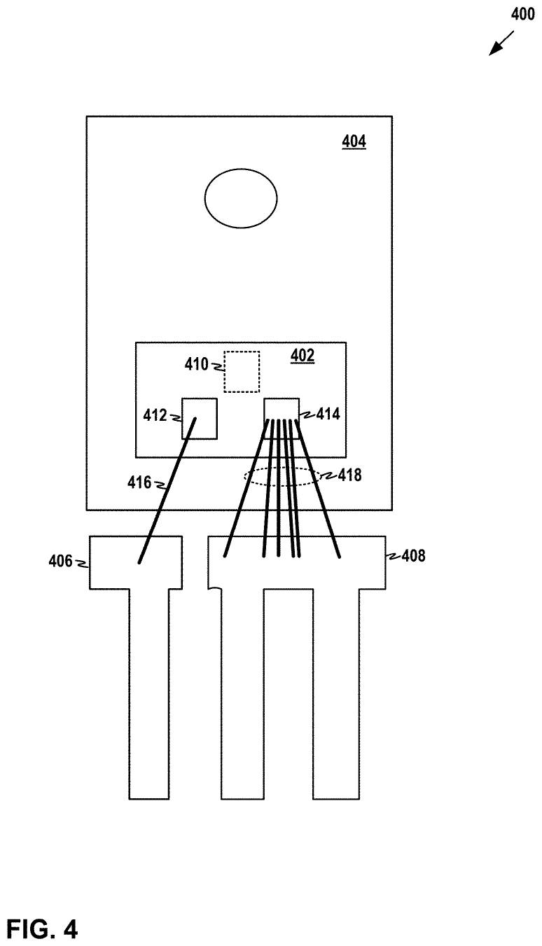

FIG. 4 is a conceptual diagram illustrating a third example of the semiconductor package 100 of FIG. 1, in accordance with one or more techniques of this disclosure. As illustrated, semiconductor package 400 includes semiconductor die 402, tab 404, first lead 406, and continuous lead frame 408. Semiconductor die 402 may be an example of semiconductor die 102 of FIG. 1. Tab 404 may be an example of tab 104 of FIG. 1. First lead 406 may be an example of first lead 106 of FIG. 1. Continuous lead frame 408 may be an example of continuous lead frame 108 of FIG. 1.

In the example of FIG. 4, wire bond 416 electronically couples second terminal 412 to first lead 406 and wire bonds 418 electronically couple third terminal 414 to continuous lead frame 408. As shown, in the example of FIG. 4, wire bonds 418 have a greater number of wire bonds than wire bond 416. For example, wire bonds 418 may include 5 or more wire bonds. In some examples, wire bonds 418 may include less than 4 wire bonds. In this example, wire bond 416 includes a single wire bond, however, in other examples, wire bond 416 may include multiple wire bonds.

In the example of FIG. 4, wire bonds 418 may have a relatively low thermal resistance compared to a wire bond for connecting to lead connection region of a single lead. In this way, semiconductor die 402 may be used at a higher power level with a lower semiconductor die temperature compared to semiconductor packages that do not include continuous lead frame 408, which may also improve a reliability of semiconductor die 402 compared to semiconductor packages that do not include continuous lead frame 408.

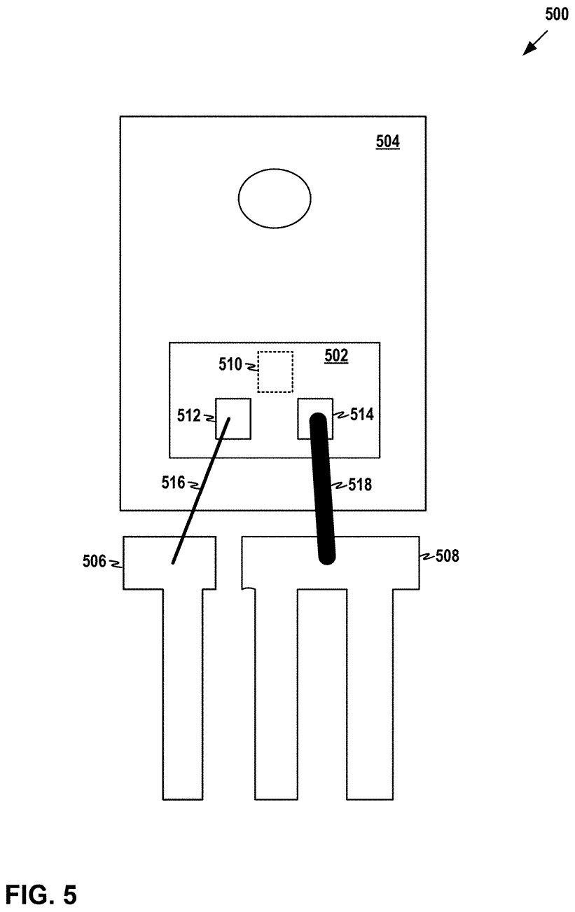

FIG. 5 is a conceptual diagram illustrating a fourth example of the semiconductor package of FIG. 1, in accordance with one or more techniques of this disclosure. As illustrated, semiconductor package 500 includes semiconductor die 502, tab 504, first lead 506, and continuous lead frame 508. Semiconductor die 502 may be an example of semiconductor die 102 of FIG. 1. Tab 504 may be an example of tab 104 of FIG. 1. First lead 506 may be an example of first lead 106 of FIG. 1. Continuous lead frame 508 may be an example of continuous lead frame 108 of FIG. 1.

In the example of FIG. 5, wire bond 516 electronically couples second terminal 512 to first lead 506 and wire bond 518 electronically couples third terminal 514 to continuous lead frame 508. As shown, in the example of FIG. 4, wire bond 518 includes a diameter greater than a diameter of wire bond 516. In this example, wire bond 516 includes a single wire bond, however, in other examples, wire bond 516 may include multiple wire bonds.

In the example of FIG. 5, wire bond 518 may have a relatively low thermal resistance compared to a wire bond for connecting to lead connection region of a single lead. In this way, semiconductor die 502 may be used at a higher power level with a lower semiconductor die temperature compared to semiconductor packages that do not include continuous lead frame 508, which may also improve a reliability of semiconductor die 502 compared to semiconductor packages that do not include continuous lead frame 508.

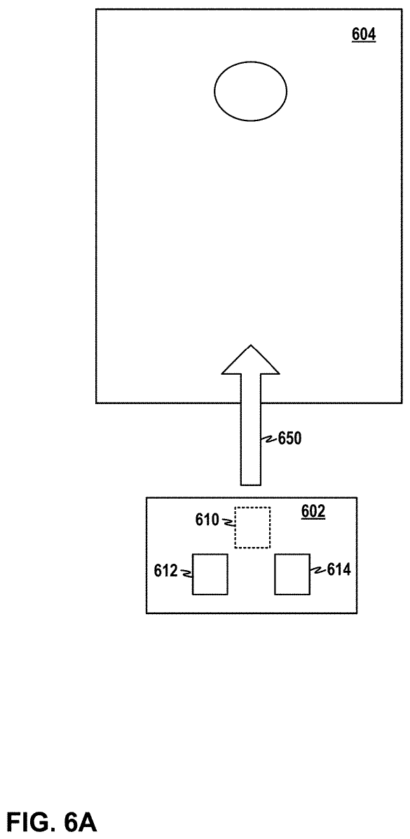

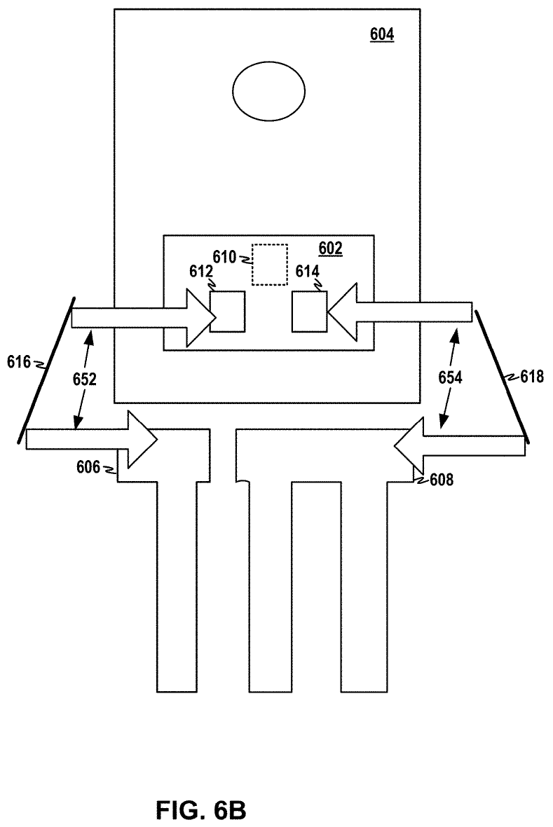

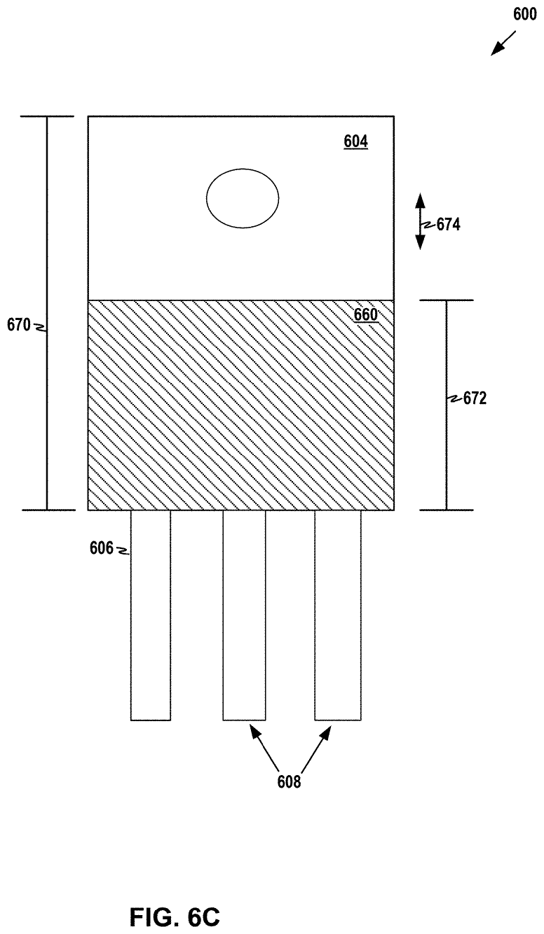

FIG. 6A-6C are conceptual illustrations of a method for providing a semiconductor package for increasing a current rating of semiconductor die, in accordance with one or more techniques of this disclosure. As shown in FIG. 6A, semiconductor die 602 is provided. For example, semiconductor die 602 is manufactured as a single discrete device or an integrated circuit.

Semiconductor die 602 may be an example of semiconductor die 102 of FIG. 1. For example, semiconductor die 602 includes a first terminal 610, a second terminal 612, and a third terminal 614. For example, first terminal 610 may include a drain of semiconductor die 602, second terminal 612 may include a gate of semiconductor die 602, and third terminal 614 may include a source of semiconductor die 602. In some examples, first terminal 610 may include a source of semiconductor die 602, second terminal 612 may include a gate of semiconductor die 602, and third terminal 614 may include a drain of semiconductor die 602. As indicated by the dashed lines in FIG. 6A, first terminal 610 may be arranged on a back surface of semiconductor die 602. In this example, second terminal 612 and third terminal 614 may be arranged on an obverse or front surface of semiconductor die 602 that is on an opposite side of semiconductor die 602 from the back surface.

Initially, semiconductor die 602 is mounted to tab 604 (650). For example, semiconductor die 602 is mounted using a conductive adhesive to tab 604. In FIG. 6B, second terminal 612 is electronically coupled to first lead 606 (652). For example, wire bond 616 is electronically coupled to second terminal 612 and to first lead 606. Wire bond 616 is an example of wire bond 116 of FIG. 1. More specifically, for instance, a first side of wire bond 616 is soldered to second terminal 612 and a second side of wire bond 616 is soldered to first lead 606.

Similarly, third terminal 614 is electronically coupled to continuous lead frame 608 (654). For example, wire bond 618 is electronically coupled to third terminal 614 and to continuous lead frame 608. Wire bond 618 is an example of wire bond 118 of FIG. 1. More specifically, for instance, a first side of wire bond 618 is soldered to third terminal 614 and a second side of wire bond 618 is soldered to continuous lead frame 608. Wire bond 618 may include a number of wire bonds greater than a number of wire bonds of wire bond 616. In some examples, wire bond 618 may include a diameter greater than a diameter of a wire bond of wire bond 616.

In FIG. 6C, mold compound 660 is formed over at least a portion of tab 604, semiconductor die 602, at least a portion of first lead 606, and at least a portion of continuous lead frame 608. Mold compound 660 may be formed of any suitable material, for example, but not limited to, an epoxy.

Semiconductor package 600 may be a TO-220 package. For example, tab 604 may comprise a length 670 of 15.3 millimeters (mm) along a vertical direction 674 of semiconductor package 600. In this example, mold compound 660 may include a length 672 of 8.7 millimeters (mm) along vertical direction 674 of semiconductor package 600.

In this way, semiconductor package 600 may represent a semiconductor package that includes a semiconductor die, a tab, a first lead, and a continuous lead frame. The semiconductor die includes a first terminal, a second terminal, and a third terminal. The tab is electronically coupled to the first terminal. The semiconductor die is mounted on the tab. The first lead is electronically coupled to the second terminal. The continuous lead frame is electronically coupled to the third terminal and includes a second lead and a third lead.

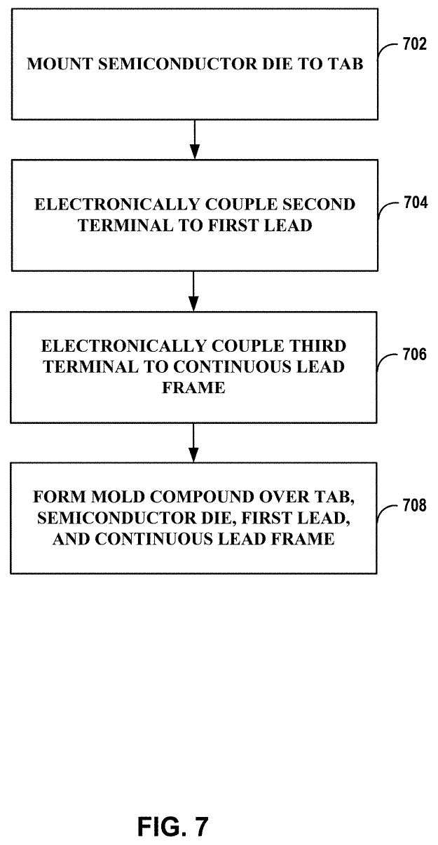

FIG. 7 is a flow diagram for a method for providing a semiconductor package for increasing a current rating of semiconductor die, in accordance with one or more techniques of this disclosure. For purposes of illustration only, FIG. 7 is described below within the context of FIGS. 6A-6C.

Initially, the method includes mounting a semiconductor die to a tab (702). For example, semiconductor die 602 is mounted using a conductive adhesive to tab 604. The method includes electronically coupling a second terminal to a first lead (704). For example, wire bond 616 is electronically coupled to second terminal 612 and to first lead 606. The method includes electronically coupling a third terminal to a continuous lead frame (706). For example, wire bond 618 is electronically coupled to third terminal 614 and to continuous lead frame 608. The method includes forming a mold compound over a tab, a semiconductor die, a first lead, and a continuous lead frame (708). For example, mold compound 660 is formed over at least a portion of tab 604, semiconductor die 602, at least a portion of first lead 606, and at least a portion of continuous lead frame 608.

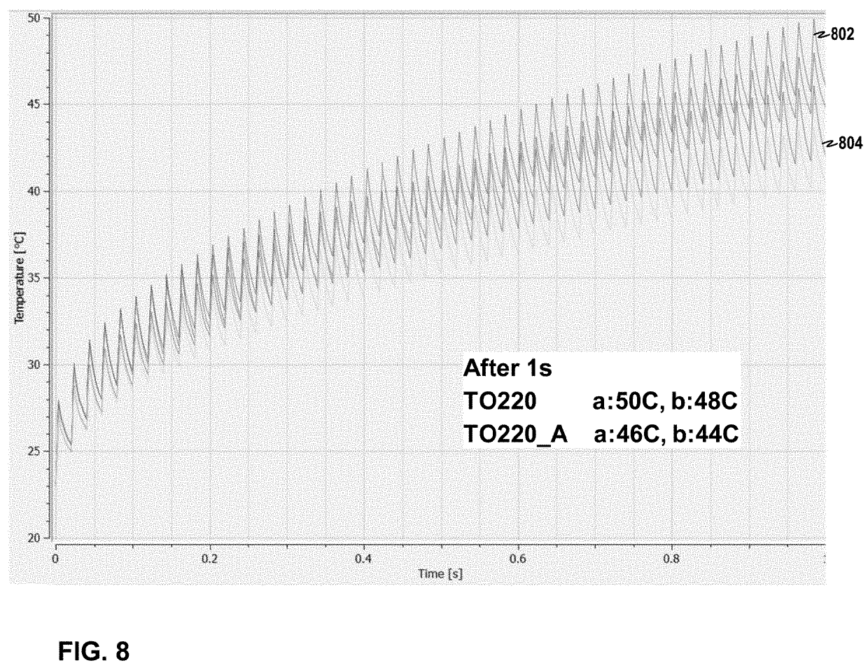

FIG. 8 is an illustration of a performance of a semiconductor package for increasing a current rating of semiconductor die after one second, in accordance with one or more techniques of this disclosure. In FIG. 8, a 100 A pulse (4 milliseconds on and 16 milliseconds off) was applied from a drain to a source of a semiconductor die arranged in a first semiconductor package and from a drain to a source of a semiconductor die arranged in a second semiconductor package.

In the first semiconductor package a gate of the semiconductor die is connected to a first lead, a drain of the semiconductor die is connected to second lead, and a source of the semiconductor die is connected to a third lead. In the second semiconductor package a drain of the semiconductor die is connected to a tab, a gate of the semiconductor die is connected to first lead, and a source of the semiconductor die is connected to a continuous lead frame. For instance, the second semiconductor package may be substantially similar to semiconductor package 100 of FIG. 1., semiconductor package 200 of FIG. 2, semiconductor package 300 of FIG. 3, semiconductor package 400 of FIG. 4, semiconductor package 500 of FIG. 5, and/or semiconductor package 600 of FIG. 6C.

The abscissa axis (e.g., horizontal) of FIG. 8 represents time and the ordinate axis (e.g., vertical) of FIG. 8 represents a wire bond temperate 802 at the first semiconductor package and a wire bond temperate 804 at the second semiconductor package. As shown, at about 1 second, wire bond temperature 802 peaks at 50 degrees Celsius (° C.) and drops to 48 degrees Celsius (° C.). At about 1 second, however, wire bond temperature 804 peaks at 46 degrees Celsius (° C.) and drops to 44 degrees Celsius (° C.). As such, FIG. 8 illustrates that the second semiconductor package (e.g., semiconductor package 100) distributes a current (e.g., drain-to-source (Ids)) over two leads, which reduces current density for each lead and joule heating in those leads compared to semiconductor packages that do not use a continuous lead frame.

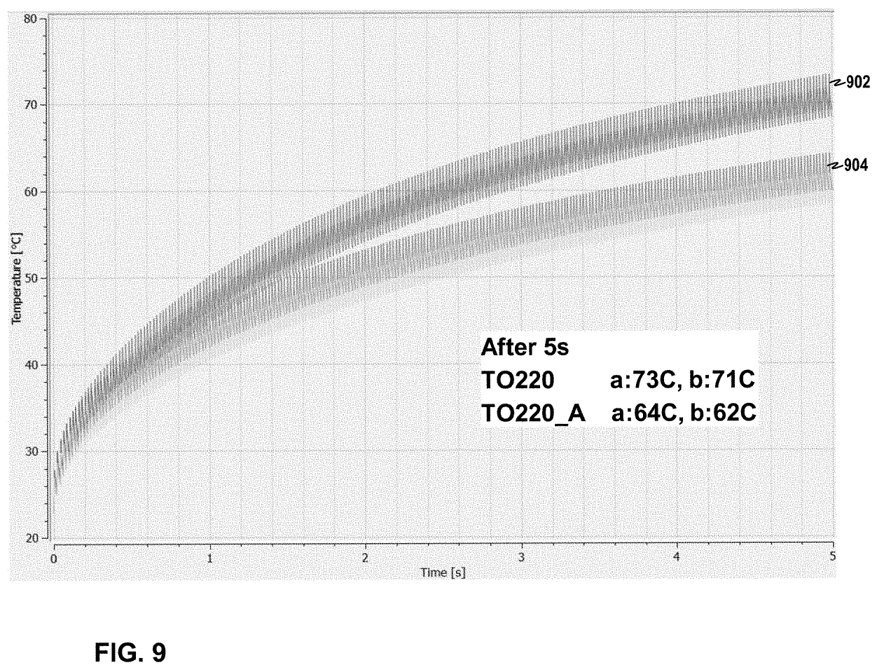

FIG. 9 is an illustration of a performance of a semiconductor package for increasing a current rating of semiconductor die after five seconds, in accordance with one or more techniques of this disclosure. In FIG. 9, a 100 A pulse (4 milliseconds on and 16 milliseconds off) was applied from a drain to a source of a semiconductor die arranged in a first semiconductor package and from a drain to a source of a semiconductor die arranged in a second semiconductor package.

In the first semiconductor package a gate of the semiconductor die is connected to a first lead, a drain of the semiconductor die is connected to second lead, and a source of the semiconductor die is connected to a third lead. In the second semiconductor package a drain of the semiconductor die is connected to a tab, a gate of the semiconductor die is connected to first lead, and a source of the semiconductor die is connected to a continuous lead frame. For instance, the second semiconductor package may be substantially similar to semiconductor package 100 of FIG. 1., semiconductor package 200 of FIG. 2, semiconductor package 300 of FIG. 3, semiconductor package 400 of FIG. 4, semiconductor package 500 of FIG. 5, and/or semiconductor package 600 of FIG. 6C.

The abscissa axis (e.g., horizontal) of FIG. 9 represents time and the ordinate axis (e.g., vertical) of FIG. 9 represents a wire bond temperate 902 at the first semiconductor package and a wire bond temperate 904 at the second semiconductor package. As shown, at about 5 seconds, wire bond temperature 902 peaks at 73 degrees Celsius (° C.) and drops to 71 degrees Celsius (° C.). At about 5 seconds, however, wire bond temperature 904 peaks at 64 degrees Celsius (° C.) and drops to 62 degrees Celsius (° C.). As such, FIG. 9 illustrates that the second semiconductor package (e.g., semiconductor package 100) distributes a current (e.g., drain-to-source (Ids)) over two leads, which reduces current density for each lead and joule heating in those leads compared to semiconductor packages that do not use a continuous lead frame.

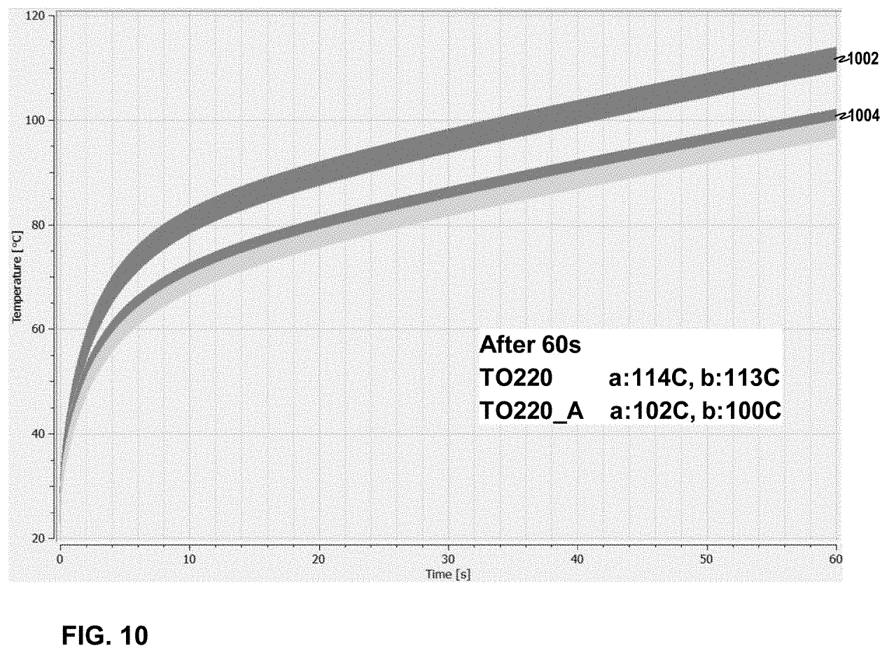

FIG. 10 is an illustration of a performance of a semiconductor package for increasing a current rating of semiconductor die after sixty seconds, in accordance with one or more techniques of this disclosure. In FIG. 10, a 100 A pulse (4 milliseconds on and 16 milliseconds off) was applied from a drain to a source of a semiconductor die arranged in a first semiconductor package and from a drain to a source of a semiconductor die arranged in a second semiconductor package.

In the first semiconductor package a gate of the semiconductor die is connected to a first lead, a drain of the semiconductor die is connected to second lead, and a source of the semiconductor die is connected to a third lead. In the second semiconductor package a drain of the semiconductor die is connected to a tab, a gate of the semiconductor die is connected to first lead, and a source of the semiconductor die is connected to a continuous lead frame. For instance, the second semiconductor package may be substantially similar to semiconductor package 100 of FIG. 1., semiconductor package 200 of FIG. 2, semiconductor package 300 of FIG. 3, semiconductor package 400 of FIG. 4, semiconductor package 500 of FIG. 5, and/or semiconductor package 600 of FIG. 6C.

The abscissa axis (e.g., horizontal) of FIG. 10 represents time and the ordinate axis (e.g., vertical) of FIG. 10 represents a wire bond temperate 1002 at the first semiconductor package and a wire bond temperate 1004 at the second semiconductor package. As shown, at about 60 seconds, wire bond temperature 1002 peaks at 114 degrees Celsius (° C.) and drops to 113 degrees Celsius (° C.). At about 60 seconds, however, wire bond temperature 1004 peaks at 102 degrees Celsius (° C.) and drops to 100 degrees Celsius (° C.). As such, FIG. 10 illustrates that the second semiconductor package (e.g., semiconductor package 100) distributes a current (e.g., drain-to-source (Ids)) over two leads, which reduces current density for each lead and joule heating in those leads compared to semiconductor packages that do not use a continuous lead frame.

The following examples may illustrate one or more aspects of the disclosure.

### EXAMPLE 1

A semiconductor package comprising: a semiconductor die comprising a first terminal, a second terminal, and a third terminal; a tab electronically coupled to the first terminal, wherein the semiconductor die is mounted on the tab; a first lead electronically coupled to the second terminal; and a continuous lead frame electronically coupled to the third terminal, the continuous lead frame comprising a second lead and a third lead.

### EXAMPLE 2

The semiconductor package of example 1, wherein the first terminal comprises a drain of the semiconductor die, wherein the second terminal comprises a gate of the semiconductor die, and wherein the third terminal comprises a source of the semiconductor die.

### EXAMPLE 3

The semiconductor package of any combination of examples 1-2, wherein the first terminal comprises a source of the semiconductor die, wherein the second terminal comprises a gate of the semiconductor die, and wherein the third terminal comprises a drain of the semiconductor die.

### EXAMPLE 4

The semiconductor package of any combination of examples 1-3, one or more first wire bonds electronically coupling the second terminal to the first lead; and one or more second wire bonds electronically coupling the third terminal to the continuous lead frame.

### EXAMPLE 5

The semiconductor package of any combination of examples 1-4, wherein the one or more second wire bonds comprises a plurality of second wire bonds, the plurality of second wire bonds having a greater number of wire bonds than the one or more first wire bonds.

### EXAMPLE 6

The semiconductor package of any combination of examples 1-5, wherein the one or more second wire bonds comprises 5 or more wire bonds.

### EXAMPLE 7

The semiconductor package of any combination of examples 1-6, wherein each wire bond of the one or more second wire bonds comprises a diameter greater than a diameter of the one or more first wire bonds.

### EXAMPLE 8

The semiconductor package of any combination of examples 1-7, wherein the tab includes a hole for mounting the semiconductor package to a heatsink.

### EXAMPLE 9

The semiconductor package of any combination of examples 1-8, wherein the semiconductor package is a TO-220 package.

### EXAMPLE 10

The semiconductor package of any combination of examples 1-9, further comprising: a mold compound formed over at least a portion of the tab, the semiconductor die, at least a portion of the first lead, and at least a portion of the continuous lead frame.

### EXAMPLE 11

A method comprising: mounting a semiconductor die to a tab, the semiconductor die comprising a first terminal, a second terminal, and a third terminal, wherein mounting the semiconductor die to the tab electronically couples the first terminal to the tab; electronically coupling the second terminal to a first lead; and electronically coupling the third terminal to a continuous lead frame, the continuous lead frame comprising a second lead and a third lead.

### EXAMPLE 12

The method of example 11, wherein the first terminal comprises a drain of the semiconductor die, wherein the second terminal comprises a gate of the semiconductor die, and wherein the third terminal comprises a source of the semiconductor die.

### EXAMPLE 13

The method of any combination of examples 11-12, wherein the first terminal comprises a source of the semiconductor die, wherein the second terminal comprises a gate of the semiconductor die, and wherein the third terminal comprises a drain of the semiconductor die.

### EXAMPLE 14

The device of any combination of examples 11-13, wherein electronically coupling the second terminal comprises electronically coupling one or more first wire bonds to the second terminal and to the first lead, and wherein electronically coupling the third terminal comprises electronically coupling one or more second wire bonds to the third terminal and to the continuous lead frame.

### EXAMPLE 15

The method of any combination of examples 11-14, wherein the one or more second wire bonds comprises a plurality of second wire bonds, the plurality of second wire bonds having a greater number of wire bonds than the one or more first wire bonds.

### EXAMPLE 16

The method of any combination of examples 11-15, wherein each wire bond of the one or more second wire bonds comprises a diameter greater than a diameter of the one or more first wire bonds.

### EXAMPLE 17

The method of any combination of examples 11-16, further comprising: forming a mold compound over at least a portion of the tab, the semiconductor die, at least a portion of the first lead, and at least a portion of the continuous lead frame.

### EXAMPLE 18

A semiconductor package comprising: a semiconductor die comprising a first terminal, a second terminal, and a third terminal; a tab electronically coupled to the first terminal, wherein the semiconductor die is mounted on the tab; a first lead; one or more first wire bonds electronically coupling the second terminal to the first lead; a continuous lead frame comprising a lead connection region, a second lead, and a third lead; and one or more second wire bonds electronically coupling the third terminal to the lead connection region of the continuous lead frame.

### EXAMPLE 19

The semiconductor package of example 18, wherein the first terminal comprises a drain of the semiconductor die, wherein the second terminal comprises a gate of the semiconductor die, and wherein the third terminal comprises a source of the semiconductor die.

### EXAMPLE 20

The semiconductor package of any combination of examples 18-19, wherein the first terminal comprises a source of the semiconductor die, wherein the second terminal comprises a gate of the semiconductor die, and wherein the third terminal comprises a drain of the semiconductor die.

Various aspects have been described in this disclosure. These and other aspects are within the scope of the following claims.

1. A semiconductor package comprising:
a semiconductor die comprising a first terminal, a second terminal, and a third terminal;
a tab electronically coupled to the first terminal, wherein the semiconductor die is mounted on the tab;
a first lead electronically coupled to the second terminal; and
a continuous lead frame electronically coupled to the third terminal, the continuous lead frame comprising a second lead and a third lead.

2. The semiconductor package of claim 1,
wherein the first terminal comprises a drain of the semiconductor die,
wherein the second terminal comprises a gate of the semiconductor die, and
wherein the third terminal comprises a source of the semiconductor die.

3. The semiconductor package of claim 1,
wherein the first terminal comprises a source of the semiconductor die,
wherein the second terminal comprises a gate of the semiconductor die, and
wherein the third terminal comprises a drain of the semiconductor die.

4. The semiconductor package of claim 1, further comprising:
one or more first wire bonds electronically coupling the second terminal to the first lead; and
one or more second wire bonds electronically coupling the third terminal to the continuous lead frame.

5. The semiconductor package of claim 4, wherein the one or more second wire bonds comprises a plurality of second wire bonds, the plurality of second wire bonds having a greater number of wire bonds than the one or more first wire bonds.

6. The semiconductor package of claim 4, wherein the one or more second wire bonds comprises 5 or more wire bonds.

7. The semiconductor package of claim 4, wherein each wire bond of the one or more second wire bonds comprises a diameter greater than a diameter of the one or more first wire bonds.

8. The semiconductor package of claim 1, wherein the tab includes a hole for mounting the semiconductor package to a heatsink.

9. The semiconductor package of claim 1, wherein the semiconductor package is a TO-220 package.

10. The semiconductor package of claim 1, further comprising:
a mold compound formed over at least a portion of the tab, the semiconductor die, at least a portion of the first lead, and at least a portion of the continuous lead frame.

11. A method comprising:
mounting a semiconductor die to a tab, the semiconductor die comprising a first terminal, a second terminal, and a third terminal, wherein mounting the semiconductor die to the tab electronically couples the first terminal to the tab;
electronically coupling the second terminal to a first lead; and
electronically coupling the third terminal to a continuous lead frame, the continuous lead frame comprising a second lead and a third lead.

12. The method of claim 11,
wherein the first terminal comprises a drain of the semiconductor die,
wherein the second terminal comprises a gate of the semiconductor die, and
wherein the third terminal comprises a source of the semiconductor die.

13. The method of claim 11,
wherein the first terminal comprises a source of the semiconductor die,
wherein the second terminal comprises a gate of the semiconductor die, and
wherein the third terminal comprises a drain of the semiconductor die.

14. The method of claim 11,
wherein electronically coupling the second terminal comprises electronically coupling one or more first wire bonds to the second terminal and to the first lead, and
wherein electronically coupling the third terminal comprises electronically coupling one or more second wire bonds to the third terminal and to the continuous lead frame.

15. The method of claim 14, wherein the one or more second wire bonds comprises a plurality of second wire bonds, the plurality of second wire bonds having a greater number of wire bonds than the one or more first wire bonds.

16. The method of claim 14, wherein each wire bond of the one or more second wire bonds comprises a diameter greater than a diameter of the one or more first wire bonds.

17. The method of claim 11, further comprising:
forming a mold compound over at least a portion of the tab, the semiconductor die, at least a portion of the first lead, and at least a portion of the continuous lead frame.

18. A semiconductor package comprising:
a semiconductor die comprising a first terminal, a second terminal, and a third terminal;
a tab electronically coupled to the first terminal, wherein the semiconductor die is mounted on the tab;
a first lead;
one or more first wire bonds electronically coupling the second terminal to the first lead;
a continuous lead frame comprising a lead connection region, a second lead, and a third lead; and
one or more second wire bonds electronically coupling the third terminal to the lead connection region of the continuous lead frame.

19. The semiconductor package of claim 18,
wherein the first terminal comprises a drain of the semiconductor die,
wherein the second terminal comprises a gate of the semiconductor die, and
wherein the third terminal comprises a source of the semiconductor die.

20. The semiconductor package of claim 18,
wherein the first terminal comprises a source of the semiconductor die,
wherein the second terminal comprises a gate of the semiconductor die, and
wherein the third terminal comprises a drain of the semiconductor die.
